(19) United States
(12) Patent Application Publication
(10) Pub. No.: US 2019/0086443 A1
(43) Pub. Date: Mar. 21, 2019

(54) PROBE CARD DEVICE AND ROUND PROBE THEREOF

(71) Applicant: CHUNGHWA PRECISION TEST TECH. CO., LTD., TAOYUAN CITY (TW)

(72) Inventors: WEI-JHIH SU, TAICHUNG CITY (TW); CHIH-PENG HSIEH, TAIPEI CITY (TW)

(21) Appl. No.: 15/810,201

(22) Filed: Nov. 13, 2017

(30) Foreign Application Priority Data
Sep. 15, 2017 (TW) 106131780

(51) Int. Cl. G01R 1/073; G01R 1/067

(52) U.S. Cl. CPC G01R 1/07335; G01R 1/06733; G01R 1/06755; G01R 1/07378

(57) ABSTRACT

A round probe of a probe card device includes a metallic pin and insulating latch. The outside diameter of the metallic pin is smaller than or equal to 40 μm. The metallic pin includes a middle segment, a first connecting segment and a second connecting segment respectively extending from two opposite ends of the middle segment, and a first contacting segment and a second contacting segment respectively extending from the first and second connecting segments in two opposite directions away from the middle segment. The insulating latch is formed on a part of the first contacting segment, and an end portion of the first contacting segment protruding from the insulating latch is defined as a protrusion. A maximum distance between an outer surface of the insulating latch and an adjacent outer surface of the metallic pin is smaller than or equal to the outside diameter of the metallic pin.

### BACKGROUND OF THE INVENTION

### 1. Field of the Invention

The present disclosure relates to a probe card; in particular, to a probe card device and a round probe thereof.

### 2. Description of Related Art

In a testing process of semi-conductor wafers, a testing apparatus is electrically connected to an object to be tested by using a probe card device, and the testing apparatus can obtain a testing result of the object by signal transmission and signal analysis. The conventional probe card device has a plurality of probes corresponding in position to electrical pads of the object, and the probes are used to simultaneously and respectively contact the electrical pads of the object.

Specifically, the probes of the conventional probe card device can be round probes, which can be made by using a drawing technology to form an outside diameter thereof smaller than or equal to 40 μm. However, if the outside diameter of the conventional round probe is smaller than or equal to 40 μm, the conventional round probe easily falls outside the range of the probe head, such that the assembling of the conventional round probe becomes very difficult.

### SUMMARY OF THE INVENTION

The present disclosure provides a probe card device and a round probe thereof to effectively improve the drawbacks associated with conventional round probes.

The present disclosure discloses a probe card device, which includes an upper die, a lower die, and a plurality of round probes. The upper die has a plurality of first thru-holes, and each of the first thru-holes has a first aperture. The lower die has a plurality of second thru-holes and is substantially parallel to the upper die. The second thru-holes respectively correspond in position to the first thru-holes, and each of the second thru-holes has a second aperture smaller than the first aperture. The round probes respectively pass through the first thru-holes and respectively pass through the second thru-holes. Each of the round probes includes a metallic pin and an insulating latch formed on the metallic pin. An outside diameter of the metallic pin of each of the round probes is smaller than or equal to 40 μm, smaller than the first aperture, and smaller than the second aperture. The metallic pin of each of the round probes includes a middle segment, a first connecting segment, a second connecting segment, a first contacting segment, and a second contacting segment. The middle segment is arranged between the upper die and the lower die. The first connecting segment extends from an end of the middle segment and is arranged in the corresponding first thru-hole. The second connecting segment extends from the other end of the middle segment and is arranged in the corresponding second thru-hole. The first contacting segment extends from the first connecting segment and is arranged outside the corresponding first thru-hole. The second contacting segment extends from the second connecting segment and is arranged outside the corresponding second thru-hole. In each of the round probes, the insulating latch is formed on the first contacting segment of the metallic pin, an end portion of the first contacting segment protrudes from the insulating latch and is defined as a protrusion, and an outside diameter jointly formed by the insulating latch and the first contacting segment is larger than the second aperture and larger than the first aperture.

The present disclosure also discloses a round probe of a probe card device, which includes a metallic pin and an insulating latch. The metallic pin has an outside diameter smaller than or equal to 40 μm and includes a middle segment, a first connecting segment, a second connecting segment, a first contacting segment, and a second contacting segment. The first connecting segment and the second connecting segment respectively extend from two opposite ends of the middle segment. The first contacting segment extends from the first connecting segment in a direction away from the middle segment. The second contacting segment extends from the second connecting segment in a direction away from the middle segment. The insulating latch is formed on a part of the first contacting segment of the metallic pin. An end portion of the first contacting segment protrudes from the insulating latch and is defined as a protrusion, and a maximum distance between an outer surface of the insulating latch and an adjacent portion of the outer surface of the metallic pin is smaller than or equal to the outside diameter of the metallic pin.

In summary, for the round probe or the probe card device in the present disclosure, the metallic pin having an outside diameter smaller than or equal to 40 μm is provided with the insulating latch formed on the first contacting segment thereof, and an outside diameter of the round probe larger than the first aperture is formed by the insulating latch and the corresponding portion of the first contacting segment, thereby effectively preventing the round probe from falling outside the range of the probe head through the first thru-hole during the assembly of the round probe.

In order to further appreciate the characteristics and technical contents of the present disclosure, references are hereunder made to the detailed descriptions and appended drawings in connection with the present disclosure. However, the appended drawings are merely shown for exemplary purposes, and should not be construed as restricting the scope of the present disclosure.

### BRIEF DESCRIPTION OF THE DRAWINGS

FIG. 1 is a perspective view showing a probe card device according to an embodiment of the present disclosure, in which a space transformer is omitted;

FIG. 2 is an exploded view of a part of FIG. 1;

FIG. 3 is a cross-sectional view taken along a cross-sectional line III-III of FIG. 1;

FIG. 4 is a perspective view showing a round probe in a first variation structure according to the present disclosure;

FIG. 5 is a perspective view showing the round probe in a second variation structure according to the present disclosure; and

FIG. 6 is a perspective view showing the round probe in a third variation structure according to the present disclosure.

### DETAILED DESCRIPTION OF THE PREFERRED EMBODIMENTS

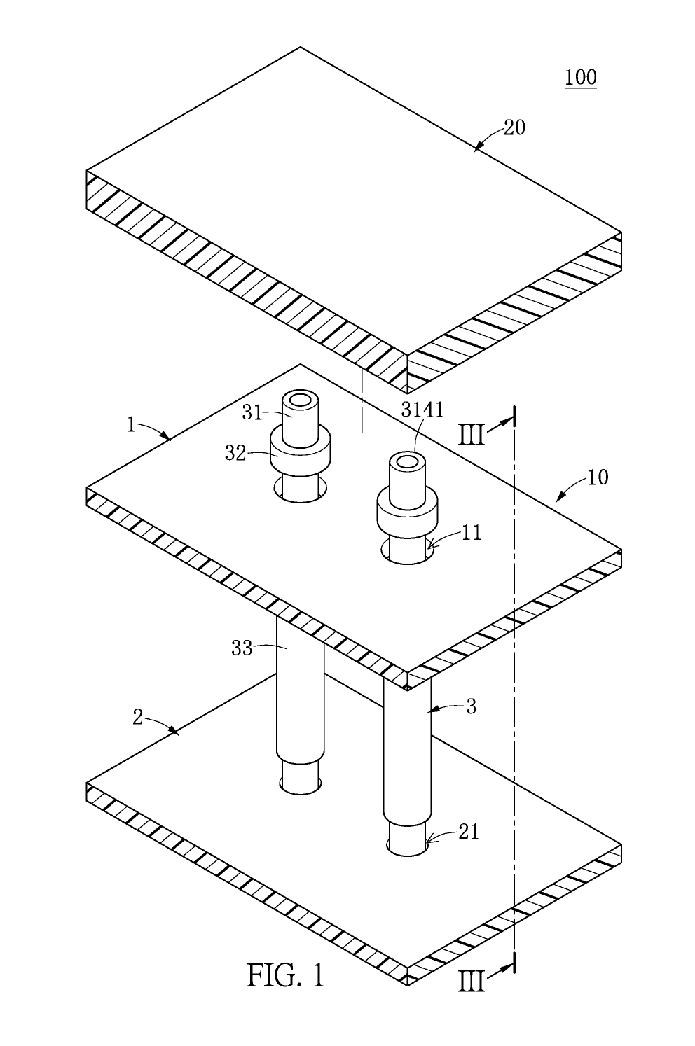

Reference is made to FIGS. 1 to 6, which illustrate the present disclosure. References are hereunder made to the detailed descriptions and appended drawings in connection with the present disclosure. However, the appended drawings are merely provided for exemplary purposes, and should not be construed as restricting the scope of the present disclosure.

Reference is first made to FIGS. 1 to 3, which illustrate an embodiment of the present disclosure. The present embodiment discloses a probe card device 100. The probe card device 100 includes a probe head 10 and a space transformer 20 abutted against one side of the probe head 10 (i.e., the top side of the probe head 10 as shown in FIG. 1), and the other side of the probe head 10 (i.e., the bottom side of the probe head 10 as shown in FIG. 1) can be used for contacting and testing an object to be tested, such as a semi-conductor wafer (not shown).

To facilitate a better understanding of the structure and connection of each component of the probe card device 100 according to the present embodiment, the figures show only part of the probe card device 100. The following description discloses the structure and connection of each component of the probe card device 100.

The probe head 10 includes an upper die 1, a lower die 2 substantially parallel to the upper die 1, a spacer (not shown) sandwiched between the upper die 1 and the lower die 2, and a plurality of round probes 3. The upper die 1 has a plurality of first thru-holes 11, and each of the first thru-holes 11 has a first aperture D11. The lower die 2 has a plurality of second thru-holes 21 respectively corresponding in position to the first thru-holes 11, and each of the second thru-holes 21 has a second aperture D21 smaller than the first aperture D11.

Moreover, the round probes 3 are substantially in a matrix arrangement. Each of the round probes 3 sequentially passes through the corresponding first thru-hole 11 of the upper die 1, the spacer, and the corresponding second thru-hole 21 of the lower die 2. The present embodiment does not disclose the detailed structure of the spacer.

While in a more specific sense, the round probe 3 in the present embodiment may be paired with the upper die 1, the spacer, and the lower die 2 for description, the practical application of the round probe 3 is not limited thereto. The probe card device 100 in the present embodiment is limited to using the round probe 3, which can be made by using a drawing technique, so that the present embodiment excludes any rectangular probe made by a different production process (e.g., MEMS technology). In other words, since the production process of the round probe 3 is drastically different from that of any rectangular probe, the rectangular probe does not provide any motivation for the production of the round probe 3.

As the round probes 3 are of the same structure, the following description only discloses the structure of one of the round probes 3 for the sake of brevity. However, in other embodiments of the present disclosure, the round probes 3 of the probe head 10 can be formed with different structures.

The round probe 3 includes a metallic pin 31, an insulating latch 32 formed on the metallic pin 31, and an insulating layer 33 formed on the metallic pin 31 and spaced from the insulating latch 32. In other embodiments of the present disclosure, the round probe 3 can be provided without the insulating layer 33.

The metallic pin 31 in the present embodiment is conductive and has a flexible straight structure. Any cross section of the metallic pin 31 perpendicular to a longitudinal direction of the metallic pin 31 has the same circle shape. In other words, the metallic pin 31 is made by a drawing process, and an outer surface of the metallic pin 31 is formed without any concave or convex in the drawing process. Moreover, an outside diameter D31 of the metallic pin 31 is smaller than or equal to 40 μm, and the outside diameter D31 is preferably smaller than the first aperture D11 and smaller than the second aperture D21.

Specifically, the metallic pin 31 in the present embodiment includes an internal pin 31a and an external pin 31b covering an outer surface of the internal pin 31a, and a central axis of the internal pin 31a is overlapped with that of the external pin 31b. In addition, the internal pin 31a can be substantially and entirely embedded in the external pin 31b. A Young's modulus of the external pin 31b is larger than that of the internal pin 31a, so that the round probe 3 can be provided with a better mechanical strength by using the external pin 31b. An electric conductivity of the internal pin 31a is larger than that of the external pin 31b, so that the round probe 3 can be provided with a better current conduction property by using the internal pin 31a. However, the structure of the metallic pin 31 is not limited to the present embodiment. In other embodiment of the present disclosure, the metallic pin 31 can be made of a single material.

In the present embodiment, the Young's modulus of the internal pin 31a is within a range of 40˜100 Gpa, the electric conductivity of the internal pin 31a is larger than or equal to 5.0×10⁻⁴ S·m⁻¹, the Young's modulus of the external pin 31b is larger than or equal to 100 Gpa, and the electric conductivity of the external pin 31b is larger than or equal to 4.6×10⁻⁴ S·m⁻¹, but the internal pin 31a and the external pin 31b are not limited thereto. Moreover, the material of the internal pin 31a or the material of the external pin 31b can be gold, silver, copper, nickel, cobalt, or an alloy thereof. The material of the metallic pin 31 is preferably copper, a copper alloy, a nickel-cobalt alloy, or a palladium-nickel alloy, but the present disclosure is not limited thereto.

As shown in FIGS. 1 to 3, the metallic pin 31 includes a middle segment 311, a first connecting segment 312 and a second connecting segment 313 respectively extending from two opposite ends of the middle segment 311, a first contacting segment 314 extending from the first connecting segment 312 in a direction away from the middle segment 311, and a second contacting segment 315 extending from the second connecting segment 313 in a direction away from the middle segment 311.

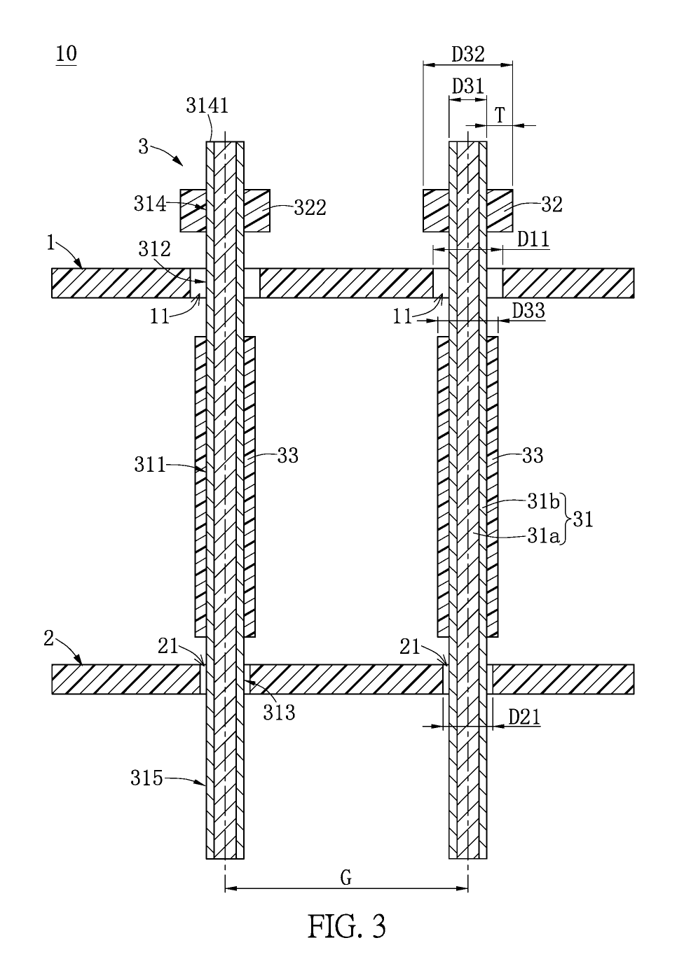

In other words, in a direction from the space transformer 20 toward the object to be tested (i.e., from an upper side to a lower side as shown in FIG. 3), the metallic pin 31 sequentially has the first contacting segment 314, the first connecting segment 312, the middle segment 311, the second connecting segment 313, and the second contacting segment 315. The first contacting segment 314 is arranged outside the corresponding first thru-hole 11 and is connected to the corresponding pad of the space transformer 20. The first connecting segment 312 is arranged in the corresponding first thru-hole 11. The middle segment 311 is arranged between the upper die 1 and the lower die 2. The second connecting segment 313 is arranged in the corresponding second thru-hole 21. The second contacting segment 315 is arranged outside the corresponding second thru-hole 21 and is connected to the corresponding pad of the object to be tested (not shown).

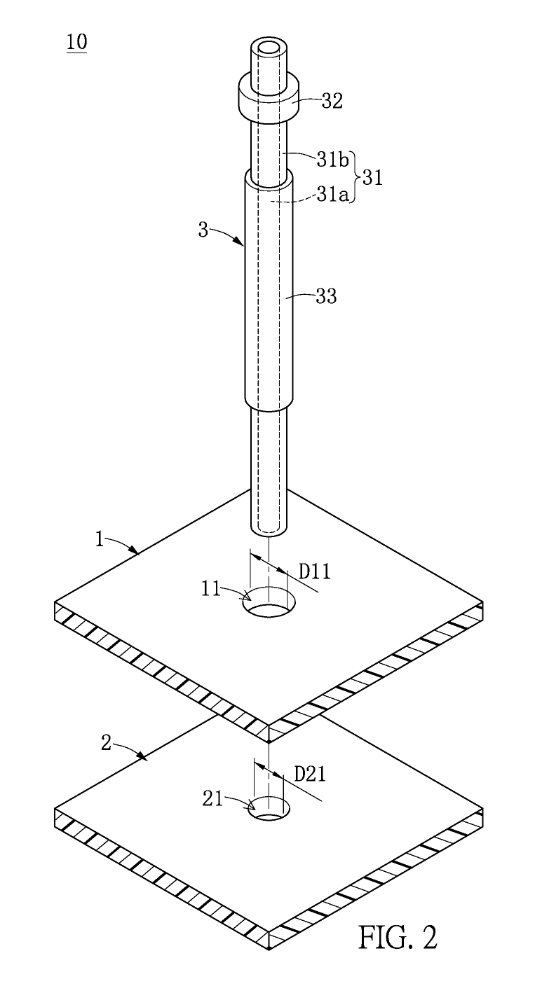

As shown in FIGS. 2 and 3, the insulating latch 32 is formed on a part of the first contacting segment 314 of the metallic pin 31, and an end portion of the first contacting segment 314 (i.e., a free end portion of the first contacting segment 314 as shown in FIG. 3) protrudes from the insulating latch 32 and is defined as a protrusion 3141. In other words, the insulating latch 32 in the present embodiment is formed on the middle part of the first contacting segment 314, and not the end part of the first contacting segment 314.

Moreover, an outside diameter D32 jointly formed by the insulating latch 32 and the first contacting segment 314 is larger than the second aperture D21 and larger than the first aperture D11. A maximum distance T between an outer surface of the insulating latch 32 and an adjacent portion of the outer surface of the metallic pin 31 is smaller than or equal to the outside diameter D31 of the metallic pin (i.e., 40 μm).

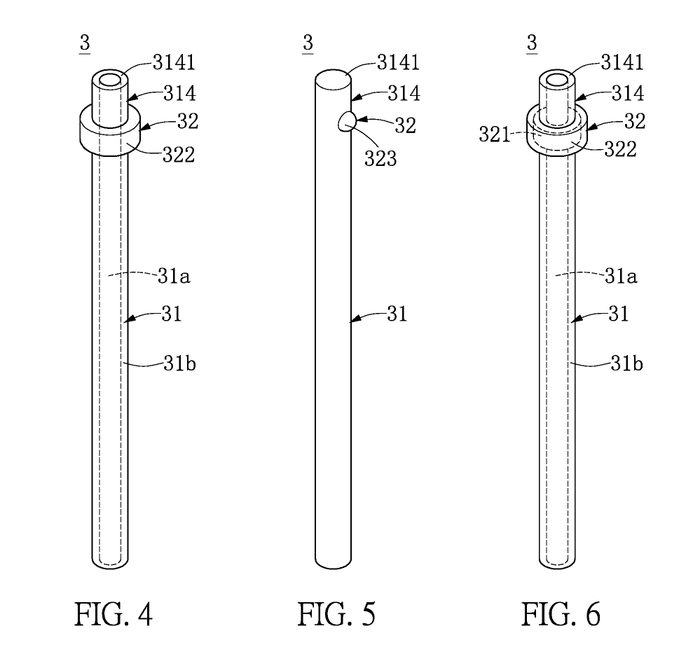

Specifically, the structure of the insulating latch 32 can be changed according to designer demands, and the following description discloses some possible structures thereof, but the present disclosure is not limited thereto. As shown in FIG. 4, the insulating latch 32 is an insulating gel layer 322 adhered to the first contacting segment 314 and having a circular-ring shape. As shown in FIG. 5, the insulating latch 32 is an insulating gel protrusion 323 adhered to the first contacting segment 314. As shown in FIG. 6, the insulating latch 32 includes a metallic coating layer 321 and an insulating gel layer 322, the metallic coating layer 321 is coated on the first contacting segment 314 and has a circular-ring shape, and the metallic coating layer 321 is entirely embedded in the insulating gel layer 322.

As shown in FIG. 3, the insulating layer 33 is formed on the middle segment 311 of the metallic pin 31, that is to say, the insulating layer 33 is arranged between the upper die 1 and the lower die 2. An outside diameter D33 jointly defined by the middle segment 311 of the metallic pin 31 and the insulating layer 33 is smaller than the first aperture D11 and is larger than the second aperture D21, so that the insulating layer 33 of the round pin 3 can pass through the first thru-hole 11 and can be provided for preventing the round pin 3 from falling outside the range of the probe head 10 through the second thru-hole 21. In addition, a distance between the insulating layer 33 and the lower die 2 is preferably equal to or smaller than a distance between the insulating latch 32 and the upper die 1, but the present disclosure is not limited thereto.

The structure of the round probe 3 has been disclosed in the above description, and the following description discloses the connection relationship between the probe head 10 and the other components of the probe card device 100. Specifically, any two adjacent metallic pins 31 of the probe head 10 have a gap G, which is preferably smaller than or equal to 100 μm, and the space transformer 20 is abutted against the protrusions 3141 of the round probes 3.

### The Effects of the Above Embodiment

In summary, for the round probe 3 or the probe card device 100 in the present disclosure, the metallic pin 31 having an outside diameter D31 smaller than or equal to 40 μm is provided with the insulating latch 32 formed on the first contacting segment 314 thereof, and an outside diameter D32 of the round probe 3 larger than the first aperture D11 is formed by the insulating latch 32 and the corresponding portion of the first contacting segment 314, thereby effectively preventing the round probe 3 from falling outside the range of the probe head 10 through the first thru-hole 11 during the assembly of the round probe 3.

Moreover, the structure of the round probe 3 in the present embodiment (i.e., the external pin 31b being integrally formed on the outer surface of the internal pin 31a) is formed so that the current conduction property of the metallic pin 31 is not affected and the mechanical strength of the metallic pin 31 can be effectively improved.

In addition, the round probe 3 in the present disclosure can be provided with the insulating layer 33 formed on the middle 311 of the metallic pin 31, the insulating layer 33 of the round probe 3 can pass through the first thru-hole 11, and the insulating layer 33 can be configured to prevent the round probe 3 from falling outside the range of the probe head 10 through the second thru-hole 21.

The descriptions illustrated supra set forth simply the preferred embodiments of the present disclosure; however, the characteristics of the present disclosure are by no means restricted thereto. All changes, alterations, or modifications conveniently considered by those skilled in the art are deemed to be encompassed within the scope of the present disclosure delineated by the following claims.

What is claimed is:

1. A probe card device, comprising:
an upper die having a plurality of first thru-holes, wherein each of the first thru-holes has a first aperture;
a lower die having a plurality of second thru-holes and substantially parallel to the upper die, wherein the second thru-holes respectively correspond in position to the first thru-holes, and each of the second thru-holes has a second aperture smaller than the first aperture; and
a plurality of round probes respectively passing through the first thru-holes and respectively passing through the second thru-holes, wherein each of the round probes includes a metallic pin and an insulating latch formed on the metallic pin, wherein an outside diameter of the metallic pin of each of the round probes is smaller than or equal to 40 μm, smaller than the first aperture, and smaller than the second aperture, wherein the metallic pin of each of the round probes includes:
a middle segment arranged between the upper die and the lower die;
a first connecting segment extending from an end of the middle segment and arranged in the corresponding first thru-hole;
a second connecting segment extending from the other end of the middle segment and arranged in the corresponding second thru-hole;
a first contacting segment extending from the first connecting segment and arranged outside the corresponding first thru-hole; and
a second contacting segment extending from the second connecting segment and arranged outside the corresponding second thru-hole;
wherein in each of the round probes, the insulating latch is formed on the first contacting segment of the metallic pin, an end portion of the first contacting segment protrudes from the insulating latch and is defined as a protrusion, and an outside diameter jointly formed by the insulating latch and the first contacting segment is larger than the second aperture and larger than the first aperture.

2. The probe card device as claimed in claim 1, wherein any two adjacent metallic pins have a gap smaller than or equal to 100 μm; wherein in each of the round probes, a maximum distance between an outer surface of the insulating latch and an adjacent portion of the outer surface of the metallic pin is smaller than or equal to 40 μm.

3. The probe card device as claimed in claim 1, wherein in each of the round probes, the insulating latch is an insulating gel layer adhered to the first contacting segment and having a circular-ring shape.

4. The probe card device as claimed in claim 1, wherein in each of the round probes, the insulating latch includes a metallic coating layer and an insulating gel layer, the metallic coating layer is coated on the first contacting segment and has a circular-ring shape, and the metallic coating layer is entirely embedded in the insulating gel layer.

5. The probe card device as claimed in claim 1, wherein each of the round probes includes an insulating layer formed on the middle segment thereof, and an outside diameter jointly formed by the insulating layer and the middle segment of each of the round probes is larger than the second aperture and smaller than the first aperture.

6. The probe card device as claimed in claim 5, wherein in each of the round probes, a distance between the insulating layer and the lower die is equal to or smaller than a distance between the insulating latch and the upper die.

7. The probe card device as claimed in claim 1, further comprising a space transformer abutted against the protrusions of the round probes.

8. The probe card device as claimed in claim 1, wherein in each of the round probes, the metallic pin includes an internal pin and an external pin covering an outer surface of the internal pin, a central axis of the internal pin is overlapped with that of the external pin, a Young's modulus of the external pin is larger than that of the internal pin, the Young's modulus of the external pin is larger than or equal to 100 Gpa, the Young's modulus of the internal pin is within a range of 40˜100 Gpa, an electric conductivity of the internal pin is larger than that of the external pin, the electric conductivity of the internal pin is larger than or equal to 5.0×10⁻⁴ S·m⁻¹, and the electric conductivity of the external pin is larger than or equal to 4.6×10⁻⁴ S·m⁻¹.

9. A round probe of a probe card device, comprising:
a metallic pin having an outside diameter smaller than or equal to 40 μm and including:
a middle segment;
a first connecting segment and a second connecting segment both respectively extending from two opposite ends of the middle segment;
a first contacting segment extending from the first connecting segment in a direction away from the middle segment; and
a second contacting segment extending from the second connecting segment in a direction away from the middle segment; and
an insulating latch formed on a part of the first contacting segment of the metallic pin, wherein an end portion of the first contacting segment protrudes from the insulating latch and is defined as a protrusion, and a maximum distance between an outer surface of the insulating latch and an adjacent portion of the outer surface of the metallic pin is smaller than or equal to the outside diameter of the metallic pin.

10. The round probe as claimed in claim 9, wherein the insulating latch is an insulating gel layer adhered to the first contacting segment and having a circular-ring shape.

11. The round probe as claimed in claim 9, wherein the insulating latch includes a metallic coating layer and an insulating gel layer, the metallic coating layer is coated on the first contacting segment and has a circular-ring shape, and the metallic coating layer is entirely embedded in the insulating gel layer.

12. The round probe as claimed in claim 9, further comprising an insulating layer formed on the middle segment thereof, wherein the metallic pin includes an internal pin and an external pin covering an outer surface of the internal pin, a central axis of the internal pin is overlapped with that of the external pin, a Young's modulus of the external pin is larger than that of the internal pin, and an electric conductivity of the internal pin is larger than that of the external pin.
